(19) United States
(12) Patent Application Publication
(10) Pub. No.: US 2004/0026769 A1
(43) Pub. Date: Feb. 12, 2004

(54) Mounting structure of electronic device and method of mounting electronic device

(76) Inventor: Satoshi Nakamura, Kyoto (JP)

Correspondence Address: MERCHANT & GOULD PC, P.O. BOX 2903, MINNEAPOLIS, MN, 55402-0903, US

(21) Appl. No.: 10/240,068

(22) PCT Filed: Mar. 29, 2001
(86) PCT No.: PCT/JP01/02702

(30) Foreign Application Priority Data
Mar. 30, 2000 (JP) 2000-094589

(51) Int. Cl. H01L 23/02

(52) U.S. Cl. 257/686

(57) ABSTRACT

The present invention provides a structure for mounting an electronic device on a pad portion (3) formed on a substrate (10) via a connection layer (9) formed utilizing solder. The pad portion (3) includes a base layer (4), and a first plating layer (5) formed on the base layer (4) in advance. In the connection layer (9), a diffusion-preventing layer (8) is formed for preventing a metal component contained in the base layer (4) from diffusing into the solder.

### TECHNICAL FIELD

The present invention relates to a structure for mounting an electronic device to a substrate and a method of mounting an electronic device.

### BACKGROUND ART

Conventionally, an electronic apparatus such as a PC incorporates a circuit board as shown in FIG. 9. The circuit board 1 includes a substrate 10 formed of glass-fiber-reinforced epoxy resin for example. The substrate has an obverse surface formed with a wiring pattern 2 and pad portions 3 connected to the wiring pattern. Electronic devices such as IC chips C or chip resistors R are mounted on the pad portions 3 by soldering.

For the soldering, use is often made of solder composed of 63 wt % of Sn and 37 wt % of Pb, for example. Solder containing Pb is advantageous because it has a relatively low melting point, relatively weak surface tension, and good wettability relative to metals. Recently however, so-called Pb-free solder which does not contain Pb is increasingly used in view of the environmental preservation, and many studies are ongoing for developing such Pb-free solder.

FIG. 10 schematically illustrates the pad portion 3 of the circuit board 1. The pad portion 3 includes a base layer 11 formed of Cu for example. As shown in FIG. 11, solder paste 12 is applied onto the base layer 11. In this case, for the solder contained in the solder paste 12, use is made of Pb-free, Sn—Ag—Cu based solder having the composition of Sn-3.0Ag-0.5Cu (Sn:Ag:Cu=96.5:3.0:0.5 by weight ratio).

The electronic device E is mounted on the pad portion 3 via the solder paste 12. In this state, the circuit board 1 is inserted into a reflow furnace for undergoing the reflowing process. Thus, the solder in the solder paste 12 is melted and then solidified to bond the electronic deice E to the pad portion 3. At this time, the solvent in the solder paste 12 evaporates due to the heat. In melting the solder in the reflowing process, Cu in the base layer 11 is diffused in the solder and combines with Sn contained in the. Sn—Ag—Cu solder to provide an alloy. Specifically, as shown in FIG. 12, Cu diffused in the solder may form a layer of metal compound 13 of Sn—Cu alloy between the base layer 11 and a solder connection layer 12′.

When the layer of the metal compound 13 has a suitable thickness, the bonding strength between the circuit board 1 and the electronic device E may be enhanced. However, when the thickness of the metal compound 13 becomes excessively large due to the excessive diffusion of Cu in the solder, the metal compound 13 may deteriorate the bonding strength.

FIG. 13 is a photographic view of a section, as magnified 10000 times, showing the joint between the base layer 11 and the solder connection layer 12′ when Sn—Ag—Cu based solder (Sn-3.0Ag-0.5Cu) is used. As can be seen from the figure, on the base layer 11 made of Cu is formed a metal compound 13 of Cu₃Sn and Su₆Sn₅ in the form of a so-called “peninsula”.

FIG. 14 is a photographic view showing the same section at the joint after a temperature cycle test. In the temperature cycle test, the sample is alternately exposed to the temperature of −55° C. for 30 minutes and to the temperature of 120° C. for 30 minutes in a total time of about 1,000 hours. As can be seen from the figure, the metal compound 13 has grown to be large. When the metal compound 13 becomes large, the pad portion 3 becomes weak relative to a bending stress from the side for example at the interface between the metal compound 13 and the solder connection layer 12′, which increases the possibility of a crack. Further, the solder of the solder connection layer 2′ may be released. In this way, the metal compound 13, when become large, causes the deterioration of the bonding strength between the circuit board 1 and the electronic device E.

In addition to the metal compound 13 formed at the interface between the base layer 11 and the solder connection layer 12′, studies by the inventor of the present invention and others have found that such a metal compound is formed also at other regions of the pad portion 3. Specifically, as shown in FIG. 15, when the electronic device E is bonded to the base layer 11 via the solder connection layer 12′, a metal compound 14 is formed at the interface between the electronic device E and the solder connection layer 12′.

FIG. 16 is a photographic view of a section, as magnified 10000 times, showing the joint between the electronic device E (e.g. a nickel plate) and the solder connection layer 12′ when Sn—Ag—Cu based solder (Sn-3.0Ag-0.5Cu) is used. FIG. 17 is a photographic view showing the same section at the joint after the temperature cycle test is performed in the above-described manner. It is found, from these figures, that the metal compound 14 is formed at the interface between the electronic component E and the solder connection layer 12′. Particularly, after the temperature cycle test, the metal compound 14 is large as shown in FIG. 17.

It is considered that when the solder melts and solidifies in the reflowing process, Cu of the base layer 11 is diffused in the solder to combine with Sn and is attracted toward a portion of a higher temperature, i.e. toward the electronic device E so that the metal compound 14 is formed at the interface between the electronic device E and the solder connection layer 12′.

FIG. 18 is a photographic view showing a section after the temperature cycle test, magnified 10000 times, at the joint between the electronic device E (e.g. a nickel plate) and the solder connection layer 12′ when Sn—Ag based solder (Sn-3.5Ag) is used. As can be seen from the figure, Cu—Sn metal compound 14 is grown to be large at the interface between the electronic device E and the solder connection layer 12′, although the solder does not contain Cu. From this result, it is found that the Cu—Sn metal compound 14 is formed probably because of Cu of the base layer 11 diffused in the solder and combined with Sn.

### DISCLOSURE OF THE INVENTION

An object of the present invention is to provide a structure for mounting an electronic device, which is capable of eliminating or at least lessening the problems described above.

According to a first aspect of the present invention, there is provided an electronic device mounting structure in which an electronic device is mounted to a conductive mount portion on a substrate via a connection layer formed utilizing solder. The conductive mount portion includes a base layer, and a first plating layer formed on the base layer in advance. The connection layer includes a diffusion-preventing layer for preventing a metal component contained in the base layer from diffusing in the solder.

In a preferred embodiment of the present invention, the diffusion-preventing layer is formed of an alloy of a metal component contained in the first plating layer and a metal component contained in the solder. More specifically, the first plating layer contains Ni, whereas the solder contains at least Sn, and the diffusion-preventing layer is formed of an alloy of Ni and Sn. Preferably, use may be made of solder containing one or a plurality of metal components in addition to Sn, and particularly, Pb-free solder.

According to the present invention, an electronic device is mounted to a circuit board as soldered to a conductive mount portion. The conductive mount portion is made up of a base layer formed of, for example, Cu on a substrate, and a first plating layer formed of, for example, Ni on the base layer. The electronic device is soldered to the conductive mount portion using Sn—Ag based, Pb-free solder or Sn—Ag—Cu based, Pb-free solder for example. At this time, Ni contained in the first plating layer is alloyed with Sn contained in the solder to form a diffusion-preventing layer of Ni—Sn on the base layer.

In the prior art structure, Cu contained in the base layer is alloyed with Sn contained in the solder to form a Cu—Sn metal compound, which deteriorates the bonding strength between the circuit board and the electronic device. According to the present invention, however, the diffusion-preventing layer serves as a barrier so that the diffusion of Cu in the solder is prevented. Therefore, it is possible to prevent the formation of a Cu—Sn metal compound so that the bonding strength between the circuit board and the electronic device can be maintained.

In a preferred embodiment of the present invention, the conductive mount portion includes a second plating layer formed on the first plating layer in advance, and the second plating layer contains Au. In this case, the second plating layer has a thickness which is equal to or larger than 0.03 μm and smaller than 0.1 μm. The provision of the second plating layer containing Au prevents the oxidization of Ni in the first plating layer.

According to a second aspect of the present invention, there is provided an electronic device mounting method for mounting an electronic device to a conductive mount portion on a substrate via a connection layer formed using solder. The method comprises the steps of forming a first plating layer on a base layer formed on a substrate to provide a conductive mount portion, disposing an electronic device on the conductive mount portion via solder paste, and forming a connection layer between the conductive mount portion and the electronic device by heating to a temperature higher than a melting point of the solder followed by cooling. In the connection layer forming step, a diffusion-preventing layer for preventing a metal component contained in the base layer from diffusing in the solder is formed in the connection layer.

With this electronic device mounting method, the diffusion preventing layer can be easily provided in the electronic device mounting structure of the present invention by forming a first plating layer containing Ni and a second plating layer containing Au on the base layer of the conductive mount portion and soldering the electronic device using solder containing Sn. Thus, the same advantages as those of the electronic device mounting structure provided according to the first aspect of the present invention can be obtained.

Other features and advantages of the present invention will become clearer from the detailed description given below with reference to the accompanying drawings.

### BRIEF DESCRIPTION OF THE DRAWINGS

FIG. 1 is a sectional view illustrating a pad portion of the electronic device mounting structure according to the present invention.

FIG. 2 is a sectional view illustrating the pad portion before solder paste is applied.

FIG. 3 is a sectional view illustrating the pad portion after solder paste is applied.

FIG. 4 is a photographic view of a section, as magnified, showing the joint between the first plating layer and the solder connection layer when Sn—Ag based solder is used.

FIG. 5 is a photographic view of a section, as magnified, showing the joint between the first plating layer and the solder connection layer when Sn—Ag—Cu based solder is used.

FIG. 6 is a photographic view of the same section as FIG. 5, as magnified, after the temperature cycle test is performed.

FIG. 7 is a photographic view of a section, as magnified, showing the joint between the first plating layer and the solder connection layer when Sn—Ag based solder is used.

FIG. 8 is a photographic view of the same section as FIG. 7, as magnified, after the temperature cycle test is performed.

FIG. 9 is a perspective view illustrating a conventional circuit board.

FIG. 10 is a sectional view illustrating a prior art pad portion before solder paste is applied.

FIG. 11 is a sectional view illustrating the prior art pad portion after solder paste is applied.

FIG. 12 is a sectional view illustrating the prior art pad portion in which a metal compound is formed.

FIG. 13 is a photographic view of a section, as magnified, showing the joint between the base layer and the solder connection layer when Sn—Ag—Cu based solder is used.

FIG. 14 is a photographic view of the same section as FIG. 13, as magnified, after the temperature cycle test is performed.

FIG. 15 is a sectional view illustrating the prior art pad portion in which a metal compound is formed.

FIG. 16 is a photographic view of a section, as magnified, showing the interface between the electronic device and the solder connection layer when Sn—Ag—Cu based solder is used.

FIG. 17 is a photographic view of the same section as FIG. 16, as magnified, after the temperature cycle test is performed.

FIG. 18 is a photographic view of a section, as magnified, showing the interface between the electronic device and the solder connection layer after the temperature cycle test is performed in the case where Sn—Ag based solder is used.

### BEST MODE FOR CARRYING OUT THE INVENTION

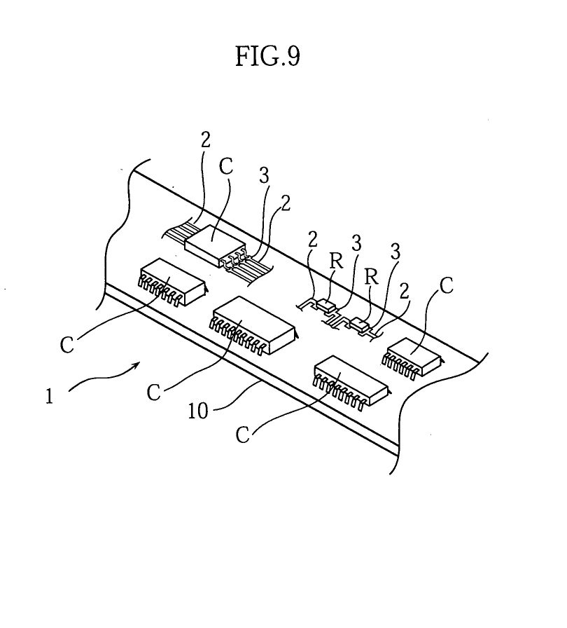

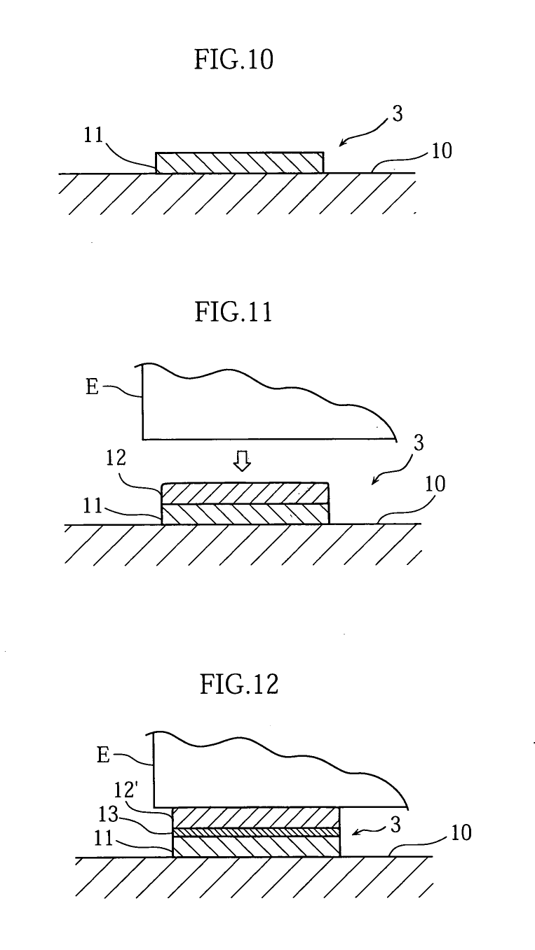

Preferred embodiments of the present invention will be described below with reference to the accompanying drawings. Throughout the drawings, the elements which are identical or similar to each other are designated by the same reference signs. In the description given below, reference is also made to FIG. 9, as required, which has been used in the description of a conventional structure.

A structure for mounting an electronic device according to an embodiment of the present invention may be applicable to such a circuit board 1 as shown in FIG. 9. The circuit board 1 includes a generally rectangular substrate 1 formed of e.g. glass-fiber-reinforced epoxy resin and having an obverse surface provided with a wiring pattern 2 formed of Cu foil for example. The wiring pattern 2 is connected, at the end portions thereof, to pad portions 3 as conductive mount portions. Electronic devices such as surface-mount type IC chips C and chip resistors R are mounted on the circuit board 1 as bonded to the pad portions 3 by soldering.

It is to be noted that the configuration of the circuit board 1 is not limited to that shown in FIG. 9. Further, electronic devices are not limited to IC chip Cs or chip resistors R but include conductive wires connected to the circuit board 1 or conductor pieces formed of a nickel plate for example.

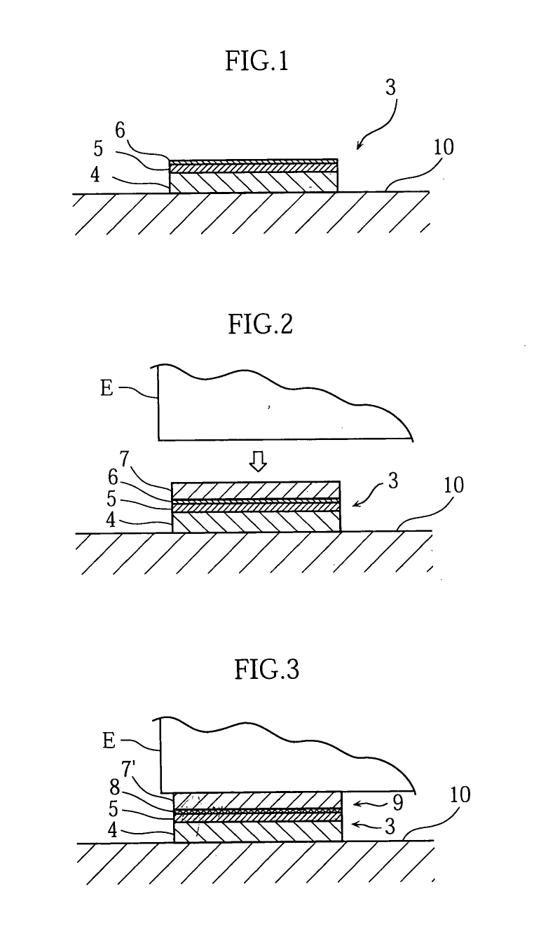

FIG. 1 schematically illustrates the sectional structure of the pad portion 3 formed on the substrate 10. The pad portion 3 comprises a base layer 4 formed on the substrate 10, a first plating layer 5 formed on the base layer 4, and a second plating layer 6 formed on the first plating layer 5.

The base layer 4 may be formed of Cu for example, and has, for example, a circular or a rectangular configuration on the substrate 10. The base layer 4 may be formed by the known photolithography into a thickness of about 35 μm.

In the photolithography, a resist material is applied to the substrate 10 provided with Cu foil. Then, after the exposure and the developing steps are performed using a mask formed with a predetermined pattern, unnecessary portions of the Cu foil are removed by etching. As a result, the base layer 4 is formed on the substrate 10. Though not illustrated in FIG. 1, the wiring pattern 2 (See FIG. 9) which is also formed of Cu is connected to the base layer 4 on the substrate 10.

The first plating layer 5 functions to prevent the base layer 4 from oxidizing. The first plating layer 5 is formed by electroplating into a thickness of about 2 μm. The first plating layer 5 may be made of Ni which has a good wettability relative to Cu of the base layer 4.

The second plating layer 6 functions to enhance the corrosion resistance and appearance of the pad portion 3. The second plating layer 6 is formed by electroplating or electroless plating or the like into a thickness which is equal to or larger than 0.03 μm and smaller than 0.1 μm. The second plating layer 6 may be made of Au. The reason why the second plating layer 6 formed of Au is provided on the first plating layer 5 formed of Ni is that it is difficult to directly plate the Cu base layer 4 with Au.

When the second plating layer 6 has a thickness which is equal to or smaller than 0.01 μm for example, there is much possibility that Ni of the first plating layer 5 beneath is oxidized, which increases the possibility of a solder failure. Therefore, the thickness of the second plating layer 6 is made equal to or larger than 0.03 μm for preventing a solder failure.

Further, when the second plating layer 6 has a thickness which is equal to or larger than 0.1 μm for example, Au in the second plating layer 6 diffuses almost entirely in the solder when the solder is applied onto the second plating layer 6. The Au diffused in the solder is combined with Sn as a component of the solder material (which will be described later) to provide an Au—Sn metal compound, which is likely to deteriorate the joint strength between the circuit board 1 and an electronic device E. Therefore, the thickness of the second plating layer 6 is made smaller than 0.1 μm for lessening the diffusion of Au in the solder and for decreasing the possibility of generation of an Au—Sn metal compound.

FIG. 2 is a sectional view illustrating the pad portion 3 in mounting the electronic device E. As shown in the figure, solder paste 7 is applied onto the second plating layer 6 of the pad portion 3. The electronic device E is disposed on the pad portion 3 via the solder paste 7.

For the solder paste, use may be made of Sn—Ag—Cu based solder, which is Pb-free. Specifically, the solder is composed of 3-5 wt % of Ag and 0.5-3 wt % of Cu, the remaining component being Sn. The solder mainly composed of Sn has a good thermal fatigue resistance and such a high thermal stability that the solder does not melt at a high temperature of 150° C. for example, thereby keeping the bonding strength.

In this embodiment, the metal components and the composition ratio of the solder is not limited to those described above. For the metal to be combined with Sn, use may be made of such metals as Bi, Sb, In, Si or other metals which can be combined with Sn to form the solder. Further, the number of metals to be combined with Sn is not limited to one.

FIG. 3 is a sectional view showing the state after the electronic device E is mounted to the circuit board 1. As shown in the figure, the electronic device E is mounted to the pad portion 3 via a connection layer 9 which includes the solder. In the connection layer 9, a diffusion-preventing layer 8 is formed which prevents Cu of the base layer 4 from diffusing into the solder. In this way, when the electronic device E is bonded to the pad portion 3 via the solder, the mounting structure changes to that as shown in FIG. 3.

The mounting structure formation process will be described below in detail. After the electronic device E is disposed on the solder paste 7, the circuit board 1 is inserted into a reflow furnace for undergoing reflow process. In the reflowing process, the solder paste is heated to melt the solder component while the solvent evaporates. At this time, it is preferable that the heating is performed at a temperature which is higher than the melting point of the solder but is lower than the maximum resistance temperature of the circuit board 1 and the electronic device E. Thereafter, the solder component is cooled for solidification so that the electronic device E is bonded to the pad portion 3 via the connection layer 9 including the solder.

When the solder melts and solidifies in the reflowing process, Au in the second plating layer 6 diffuses almost entirely into a solder connection layer 7′. Specifically, since Au is generally porous, it is fused into the component constituting the solder. At this time, as shown in FIG. 3, a diffusion-preventing layer 8 is formed at the interface between the first plating layer 5 and the solder connection layer 7′. The diffusion-preventing layer 8 is formed of an alloy of Ni, which is the metal component of the first plating layer 5, with Sn as the solder component.

In the prior art structure, when the solder is melted and solidified in the reflowing, Cu in the base layer 4 tends to combine with Sn in the solder. In this embodiment, however, the diffusion-preventing layer 8 functions as a barrier for preventing Cu of the base layer 4 from diffusing in the solder. Thus, it is possible to prevent Cu of the base layer 4 from diffusing in the solder.

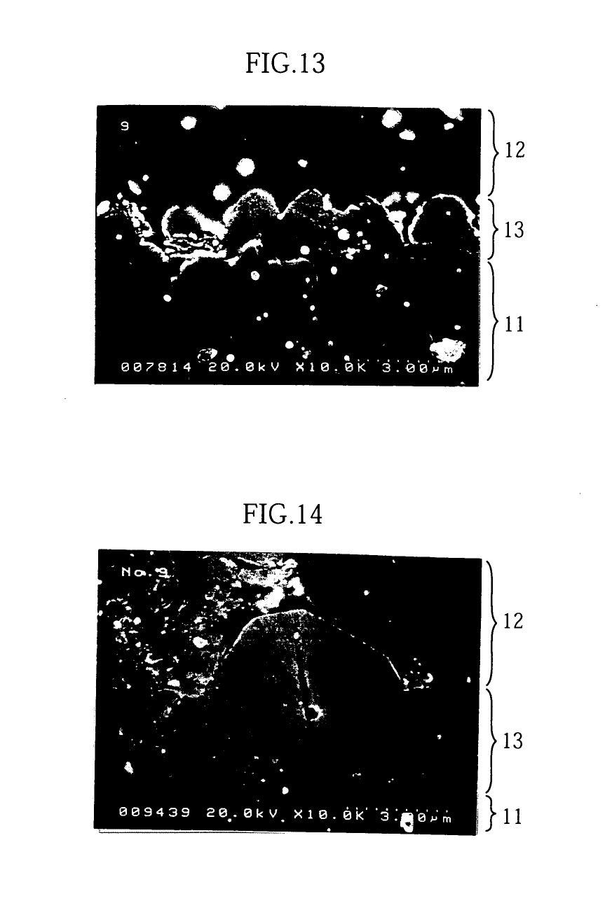

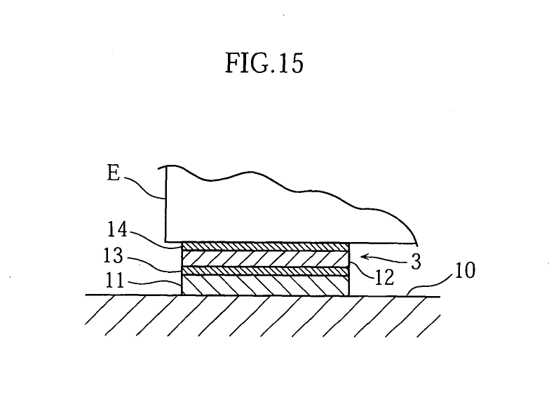

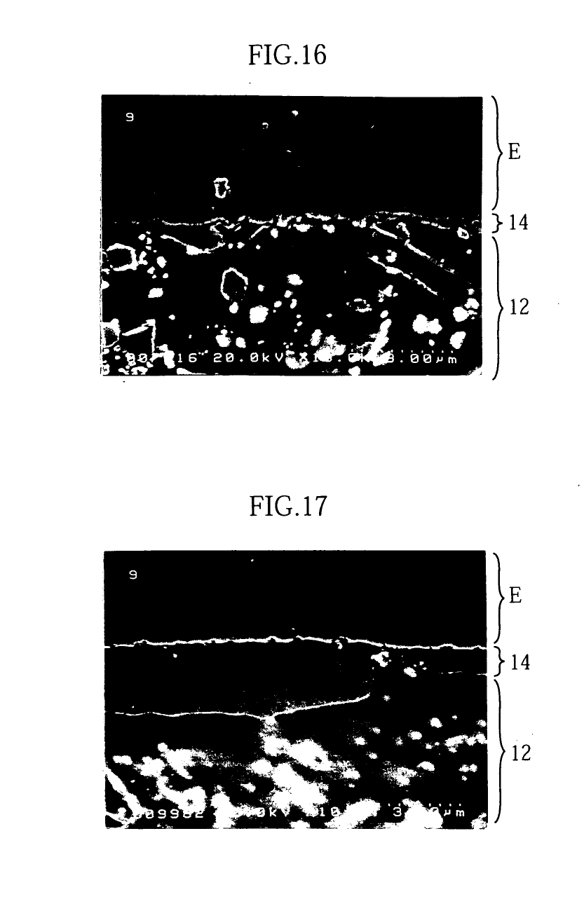

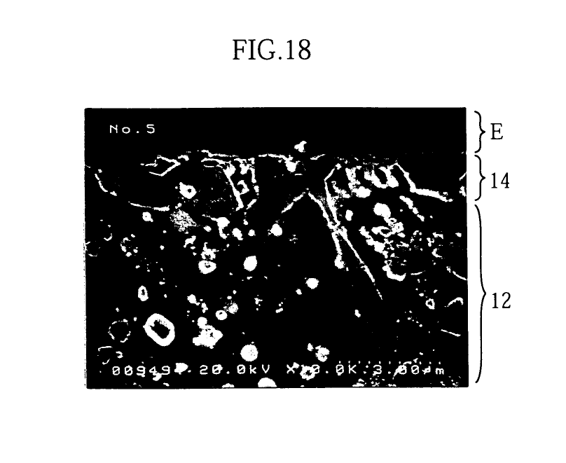

Therefore, in this embodiment, it is possible to prevent the formation of a Cu—Sn metal compound 13 (See FIGS. 13, 14) at the interface between the base layer 4 and the solder connection layer 7′, which has occurred in the prior art process. Moreover, it is also possible to prevent the formation of a Cu-Sn metal compound 14 (See FIGS. 16 and 18) at the interface between the solder connection layer 7′ and the electronic device E, which has occurred in the prior art process. Therefore, the deterioration of the connection strength between the electronic device E and the circuit board 1 due to the formation of the metal compounds can be avoided. Further, cracks in the pad portion 3 and the release of the solder due to the formation of the metal compound can also be prevented.

Since the diffusion-preventing layer 8 is relatively small in thickness because it is formed by alloying Sn in the solder with Ni in the first plating layer which is a thin film formed by electroplating for example. Therefore, the existence of the diffusion-preventing layer does not deteriorate the joint strength between the electronic device E and the circuit board 1, thereby keeping the stable bonding.

Since Pb-free solder is used in this embodiment, the requirements with respect to the environmental preservation can be met. Particularly, in this embodiment, the use of Sn—Ag—Cu based solder, which is Pb-free, makes it possible to form a solder connection layer 7′ which has a good thermal fatigue resistance and high thermal stability.

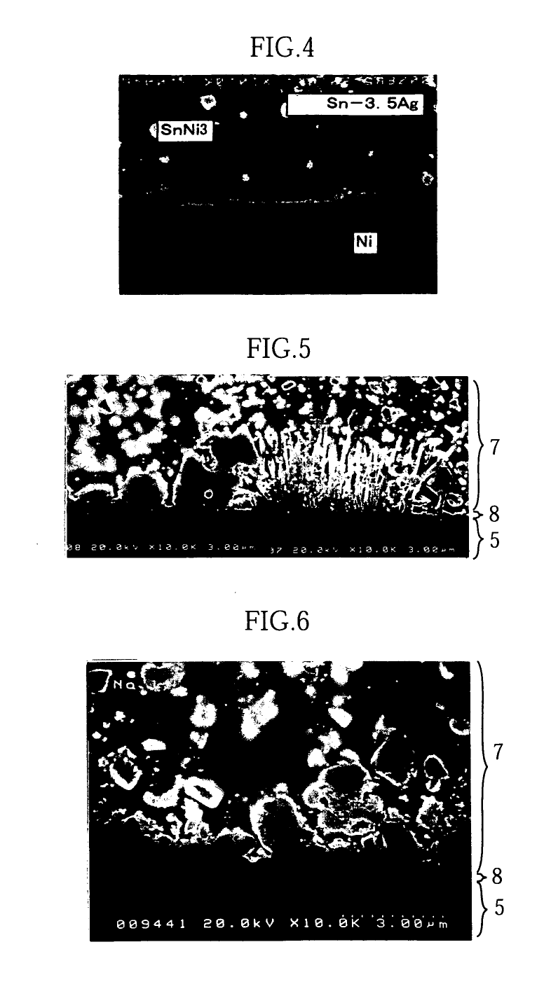

FIG. 4 is a photographic view of a section, as magnified 10000 times, showing the joint between the first plating layer 5 and the solder connection layer 7′ when Sn—Ag based solder (Sn-3.5Ag) is used for the solder connection layer 7′. As shown in the figure, a diffusion-preventing layer 8 of SnNi₃, which is a metal compound of Sn and Ni, is formed as a thin film at the interface between the first plating layer 5 and the solder connection layer 7′. Though not specifically described, the inventor of the present invention has confirmed the generation of the diffusion-preventing layer of Sn and Ni by analyzing the components of the joint at the section by EPMA (electron probe microanalysis) and by analyzing the composition in each layer of the joint at the section by ED (electron diffraction).

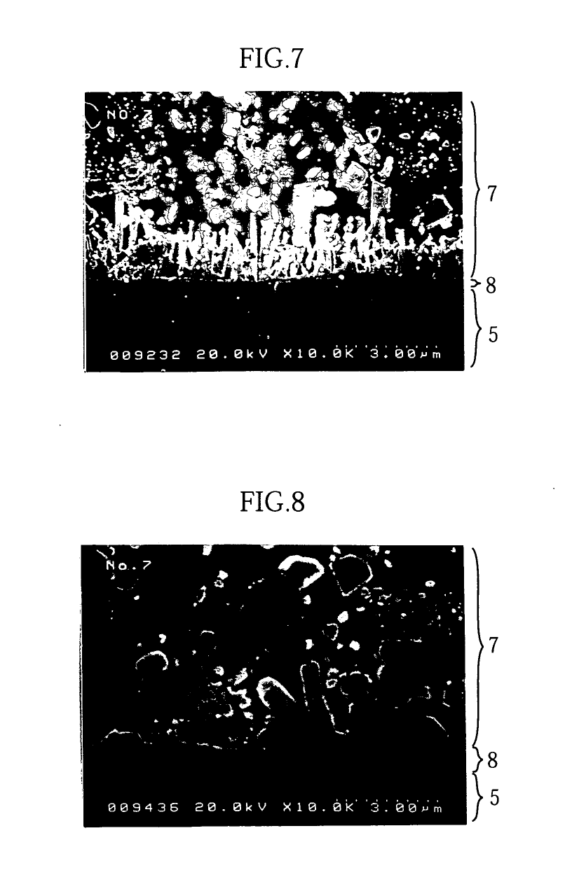

FIG. 5 is a photographic view of a section, as magnified 10000 times, showing the joint between the first plating layer 5 and the solder connection layer 7′ when Sn—Ag—Cu based solder (Sn-3.0Ag-3.5Cu) is used. FIG. 6 is a photographic view showing the same section as that of FIG. 5 after a temperature cycle test is performed. FIG. 7 is a photographic view of a section, as magnified 10000 times, showing the joint between the first plating layer 5 and the solder connection layer 7′ when Sn—Ag based solder (Sn-3.5Ag) is used. It is to be noted that FIG. 7 is a photographic view of a section which differs from that of FIG. 4. FIG. 8 is a photographic view showing the same section as FIG. 7 after the temperature cycle test is performed. As can be seen from FIGS. 5-7, the diffusion-preventing layer 8 composed of Sn and Ni is formed as a thin film at the interface between the first plating layer 5 and the solder connection layer 7′. The diffusion-preventing layer 8 prevents Cu in the base layer 4 from diffusing in the solder connection layer 7′, thereby maintaining the joint strength between the circuit board 1 and the electronic device E.

1. An electronic device mounting structure in which an electronic device is mounted to a conductive mount portion on a substrate via a connection layer formed utilizing solder;
the conductive mount portion including a base layer, and a first plating layer formed on the base layer in advance;
the connection layer including a diffusion-preventing layer for preventing a metal component contained in the base layer from diffusing into the solder.

2. The electronic device mounting structure according to claim 1, wherein the diffusion-preventing layer is formed of an alloy of a metal component contained in the first plating layer and a metal component contained in the solder.

3. The electronic device mounting structure according to claim 2, wherein the first plating layer contains Ni, whereas the solder contains at least Sn, the diffusion-preventing layer being formed of an alloy of Ni and Sn.

4. The electronic device mounting structure according to claim 3, wherein the solder contains one or a plurality of metal components in addition to Sn.

5. The electronic device mounting structure according to claim 1, wherein the conductive mount portion includes a second plating layer formed on the first plating layer in advance.

6. The electronic device mounting structure according to claim 5, wherein the second plating layer contains Au.

7. The electronic device mounting structure according to claim 5, wherein the second plating layer has a thickness which is no less than 0.03 μm and smaller than 0.1 μm.

8. An electronic device mounting method for mounting an electronic device to a conductive mount portion on a substrate via a connection layer formed using solder, the method comprising the steps of:
forming a first plating layer on a base layer formed on a substrate to provide a conductive mount portion;
disposing an electronic device on the conductive mount portion via solder paste; and
forming a connection layer between the conductive mount portion and the electronic device by heating to a temperature higher than a melting point of the solder followed by cooling;
the connection layer forming step including forming a diffusion-preventing layer in the connection layer, the diffusion-preventing layer preventing a metal component contained in the base layer from diffusing into the solder.

9. The electronic device mounting method according to claim 8, wherein the diffusion-preventing layer is formed of an alloy of a metal component contained in the first plating layer and a metal component contained in the solder.

10. The electronic device mounting method according to claim 9, wherein the first plating layer contains Ni, whereas the solder contains at least Sn, the diffusion-preventing layer being formed of an alloy of Ni and Sn.

11. The electronic device mounting method according to claim 10, wherein the solder contains one or a plurality of metal components in addition to Sn.

12. The electronic device mounting method according to claim 8, wherein the conductive mount portion further includes a second plating layer laminated on the first plating layer.

13. The electronic device mounting method according to claim 12, wherein the second plating layer contains Au.

14. The electronic device mounting method according to claim 12, wherein the second plating layer has a thickness which is no less than 0.03 μm and smaller than 0.1 μm.
